(19) United States
(12) Patent Application Publication
(10) Pub. No.: US 2023/0163550 A1
(43) Pub. Date: May 25, 2023

(54) LASER SYSTEM

(71) Applicant: Mitsubishi Electric Corporation, Tokyo (JP)

(72) Inventors: Masato KAWASAKI, Tokyo (JP); Hiroshi KIKUCHI, Tokyo (JP); Tomotaka KATSURA, Tokyo (JP)

(73) Assignee: Mitsubishi Electric Corporation, Tokyo (JP)

(21) Appl. No.: 17/922,787

(22) PCT Filed: Mar. 23, 2021
(86) PCT No.: PCT/JP2021/012002

§ 371 Date: Nov. 2, 2022

(51) Int. Cl. H01S 3/02; H01S 5/14; H01S 3/08

(52) U.S. Cl. CPC H01S 3/025; H01S 5/142; H01S 3/08009

(57) ABSTRACT

A laser system includes: a first laser element constituting one end of a first external resonator; a second laser element constituting one end of a second external resonator; a diffractive optical element to which a first beam group and a second beam group enter; a partially reflective element that constitutes an opposite end of the first external resonator and an opposite end of the second external resonator, reflects a part of the first beam and a part of the second beam, and transmits the remainder of the first beam and the remainder of the second beam; and a beam deflection element that deflects the second beam emitted from the diffractive optical element toward the partially reflective element.

### FIELD

The present disclosure relates to a laser system that couples beams emitted from a plurality of laser elements.

### BACKGROUND

A semiconductor laser element has low beam output that can be generated from a single light emitting point, and it is necessary to bundle beams generated from a plurality of semiconductor laser elements for applications such as laser machining. As a technique of a laser system that bundles beams emitted from a plurality of semiconductor laser elements, there is a proposed technique in which an external resonator including a plurality of semiconductor laser elements and a diffractive optical element is used to oscillate beams having different wavelengths at the respective semiconductor laser elements and to couple the beams into a single beam. Such a laser system has a problem that the maximum output is restricted in order to avoid damage to each optical element due to the high light intensity received by each optical element of the laser system.

Non Patent Literature 1 discloses a laser system including two external resonators that couple beams from a plurality of laser elements using a diffractive optical element, in which the two external resonators use a common diffraction grating. In the laser system according to Non Patent Literature 1, the two external resonators are assembled symmetrically with respect to the perpendicular of the diffraction grating. The laser system according to Non Patent Literature 1 couples the beams oscillated by the two external resonators and outputs the coupled beam. By using the two external resonators, it is possible to reduce the light intensity received by each optical element of the laser system.

### CITATION LIST

### Non Patent Literature

Non Patent Literature 1: “High power diode laser source with a transmission grating for two spectral beam. combining”, Optik, 2019, Vol. 192, 162918

### SUMMARY

### Technical Problem

However, according to the conventional technique disclosed in Non Patent Literature 1, the laser system requires optical elements other than the diffraction grating for each of the two external resonators, which increases the number of components. Differences in the state of adjustment of the optical elements in each external resonator or differences in the aging of the optical elements in each external resonator cause differences in the characteristics of beams output from each external resonator or change in the relative positional relation of beams in some cases. Therefore, according to the conventional technique, the laser system has problems that the number of components is increased and that variation in beam characteristics easily occurs.

The present disclosure has been made in view of the above, and it is an object of the present disclosure to obtain a laser system capable of reducing the number of components and reducing variations in beam characteristics.

### Solution to Problem

To solve the above described problems and achieve the object, a laser system according to the present disclosure includes: a first laser element adapted to emit a first beam group, the first beam group being one or a plurality of beams, and adapted to constitute one end of a first external resonator to cause the first beam group to resonate; a second laser element adapted to emit a second beam group, the second beam group being one or a plurality of beams, and adapted to constitute one end of a second external resonator to cause the second beam group to resonate; a diffractive optical element: to which the first beam group and the second beam group enter in such a manner that positive and negative angles of incidence of each beam of the first beam group and each beam of the second beam group are opposite to each other; and from which a first beam being the converged first beam group, and a second beam being the converged second beam group, are emitted; a partially reflective element adapted to constitute an opposite end of the first external resonator and an opposite end of the second external resonator, adapted to reflect a part of the first beam and a part of the second beam, and adapted to transmit the remainder of the first beam and the remainder of the second beam; and a beam deflection element adapted to deflect the second beam emitted from the diffractive optical element toward the partially reflective element.

### Advantageous Effects of Invention

A laser system according to the present disclosure has effects of reducing the number of components and reducing variations in beam characteristics.

### BRIEF DESCRIPTION OF DRAWINGS

FIG. 1 is a schematic diagram illustrating a configuration of a laser system according to a first embodiment.

FIG. 2 is a diagram for explaining an action of a transmission grating constituting the laser system according to the first embodiment.

FIG. 3 is a diagram illustrating a semiconductor laser bar that is an example of a laser element to be provided in the laser system according to the first embodiment.

FIG. 4 is a diagram illustrating an installation. example of a shield of the laser system according to the first embodiment.

FIG. 5 is a diagram for explaining a positional relation of beams in an external resonator of the laser system according to the first embodiment.

FIG. 6 is a diagram illustrating a configuration example of a laser machine to which the laser system according to the first embodiment is applied.

FIG. 7 is a schematic diagram illustrating a configuration of a laser system according to a second embodiment.

FIG. 8 is a schematic diagram illustrating a configuration of a laser system according to a third embodiment.

FIG. 9 is a diagram illustrating an example of a beam rotation element to be provided in the laser system according to the third embodiment.

FIG. 10 is a schematic diagram illustrating a configuration of a laser system according to a fourth embodiment.

FIG. 11 is a first diagram illustrating a part of a laser system according to a fifth embodiment.

FIG. 12 is a second diagram illustrating a part of the laser system according to the fifth embodiment.

FIG. 13 is a diagram illustrating a first example of a position changer of the laser system according to the fifth embodiment.

FIG. 14 is a diagram illustrating a second example of the position changer of the laser system according to the fifth embodiment.

### DESCRIPTION OF EMBODIMENTS

Hereinafter, a laser system according to embodiments will be described in detail with reference to the drawings.

### First Embodiment

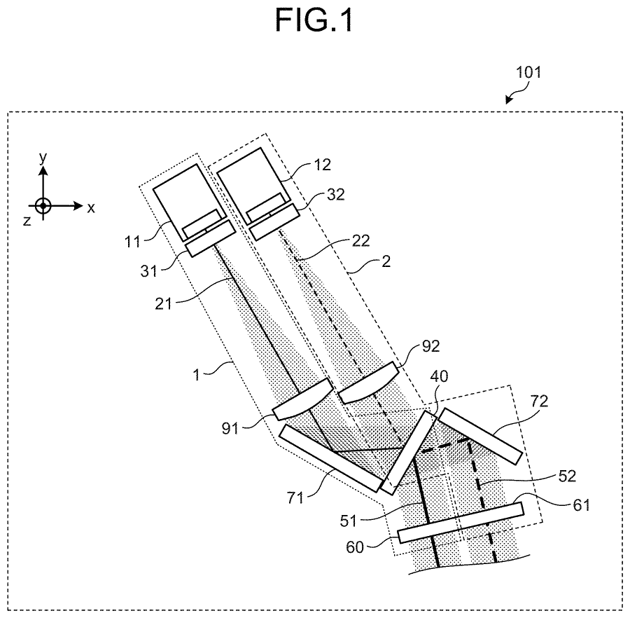

FIG. 1 is a schematic diagram illustrating a configuration of a laser system 101 according to a first embodiment. FIG. 1 illustrates an x axis, a y axis, and a z axis of a three-axis orthogonal coordinate system.

The laser system 101 includes a first laser element 11 and a second laser element 12 that are laser elements. The first laser element 11 emits a first beam group 21 that is one or a plurality of beams. The second laser element 12 emits a second beam group 22 that is one or a plurality of beams. The laser system 101 includes: a first divergence-angle correction element 31 and a second divergence-angle correction element 32 that are divergence-angle correction elements; and a transmission grating 40 that is a diffractive optical element. The first divergence-angle correction element 31 corrects the divergence angle of the first beam group 21. The second divergence-angle correction element 32 corrects the divergence angle of the second beam group 22.

In the first embodiment, the first beam group 21 includes a plurality of beams having different wavelengths. The second beam group 22 includes a plurality of beams having different wavelengths. Each beam of the first beam group 21 and each beam of the second beam group 22 propagate in the xy plane. The transmission grating 40 deflects each beam of the first beam group 21 and each beam of the second beam group 22 in the xy plane by wavelength dispersibility. The principal ray of each beam constituting the first beam group 21 and the principal ray of each beam constituting the second beam group 22 are included in the xy plane.

The laser system 101 includes: a first reflective mirror 71 and a first lens 91 that are arranged in the optical path of the first beam group 21 between the first divergence-angle correction element 31 and the transmission grating 40; and a second lens 92 arranged in the optical path of the second beam group 22 between the second. divergence-angle correction element 32 and the transmission grating 40. The first reflective mirror 71 that is a beam deflection element deflects each beam of the first beam group 21 in the xy plane. The first lens 91 collimates each beam of the first beam group 21. The second lens 92 collimates each beam of the second beam group 22.

The first beam group 21 is deflected by the first reflective mirror 71 and enters the transmission grating 40. The first beam group 21 and the second beam group 22 enter the transmission grating 40 in such a manner that the positive and negative angles of incidence of each beam of the first beam group 21 and each beam of the second beam group 22 are opposite to each other. The transmission grating 40 is arranged at a position where at least a part of the first beam group 21 deflected by the first reflective mirror 71 and at least a part of the second beam group 22 are superimposed. The transmission grating 40 deflects the first beam group 21 to converge the first beam group 21. The transmission grating 40 deflects the second beam group 22 to converge the second beam group 22. From the transmission grating 40, a first beam 51 that is the converged first beam group 21 and a second beam 52 that is the converged second beam group 22 are emitted. The principal ray of the first beam 51 and the principal ray of the second beam 52 are included in the xy plane.

The laser system 101 includes a partially reflective mirror 60 that is a partially reflective element and a second reflective mirror 72 that is a beam deflection element. The second reflective mirror 72 is arranged in the optical path of the second beam 52 between the transmission grating 40 and the partially reflective mirror 60. The second reflective mirror 72 deflects the second beam 52 in the xy plane. The second reflective mirror 72 deflects the second beam 52 emitted from the transmission grating 40 toward the partially reflective mirror 60. By deflecting the second beam 52 emitted from the transmission grating 40 by the second reflective mirror 72, the principal ray of the first beam 51 and the principal ray of the second beam 52 become parallel to each other.

The partially reflective mirror 60 reflects a part of the incident first beam 51 and transmits the remainder of the incident first beam 51. The partially reflective mirror 60 reflects a part of the incident second beam 52 and transmits the remainder of the incident second beam 52. Of the partially reflective mirror 60, an incident plane 61 to which the first beam 51 and the second beam 52 enter is a single plane. By using the partially reflective mirror 60 having the incident plane 61 that is a single plane, it is possible to realize the external resonator with a simple optical system.

A first external resonator 1 is an external resonator that causes the first beam group 21 to resonate. The first laser element 11 constitutes one end of the first external resonator 1. The partially reflective mirror 60 constitutes an opposite end of the first external resonator 1. A second external resonator 2 is an external resonator that causes the second beam group 22 to resonate. The second laser element 12 constitutes one end of the second external resonator 2. The partially reflective mirror 60 constitutes an opposite end of the second external resonator 2. The partially reflective mirror 60 is commonly used for resonance of the first beam group 21 by the first external resonator 1 and resonance of the second beam group 22 by the second external resonator 2. The transmission grating 40 is commonly used for the first external resonator 1 and the second external resonator 2.

The first beam group 21 emitted from the first laser element 11 passes through the first lens 91 and enters the first reflective mirror 71. The first reflective mirror 71 deflects the first beam group 21 toward the transmission grating 40 to cause the first beam group 21 to enter the transmission grating 40. The second beam group 22 emitted from the second laser element 12 passes through the second lens 92 and enters the transmission grating 40. The transmission grating 40 converges the first beam group 21 and converges the second beam group 22. The first beam 51 and the second beam 52 are emitted from the transmission grating 40. The first beam 51 emitted from the transmission grating 40 enters the partially reflective mirror 60. The second reflective mirror 72 deflects the second beam 52 emitted from the transmission grating 40 toward the partially reflective mirror 60 to cause the second beam 52 to enter the partially reflective mirror 60.

The first beam 51 reflected by the partially reflective mirror 60 enters the transmission grating 40. The second reflective mirror 72 deflects the second beam 52 reflected by the partially reflective mirror 60 toward the transmission grating 40 to cause the second beam 52 to enter the transmission grating 40. The transmission grating 40 causes the first beam 51 to diverge and causes the second beam 52 to diverge. Each beam of the first beam group 21 and each beam of the second beam group 22 are emitted from the transmission grating 40. The first reflective mirror 71 deflects the first beam group 21 emitted from the transmission grating 40 toward the first laser element 11. The first beam group 21 passes through the first lens 91 and enters the first laser element 11. The second beam group 22 emitted from the transmission grating 40 passes through the second lens 92 and enters the second laser element 12. The first beam 51 having passed through the partially reflective mirror 60 and the second beam 52 having passed through the partially reflective mirror 60 are emitted to the outside of the laser system 101.

In the first external resonator 1, an optical element is inserted as needed to collimate, condense, or rotate each beam of the first beam group 21 or the first beam 51. The first lens 91 is an example of an optical element that collimates each beam of the first beam group 21. In the second external resonator 2, an optical element is inserted as needed to collimate, condense, or rotate each beam of the second beam group 22 or the second beam 52. The second lens 92 is an example of an optical element that collimates each beam of the second beam group 22.

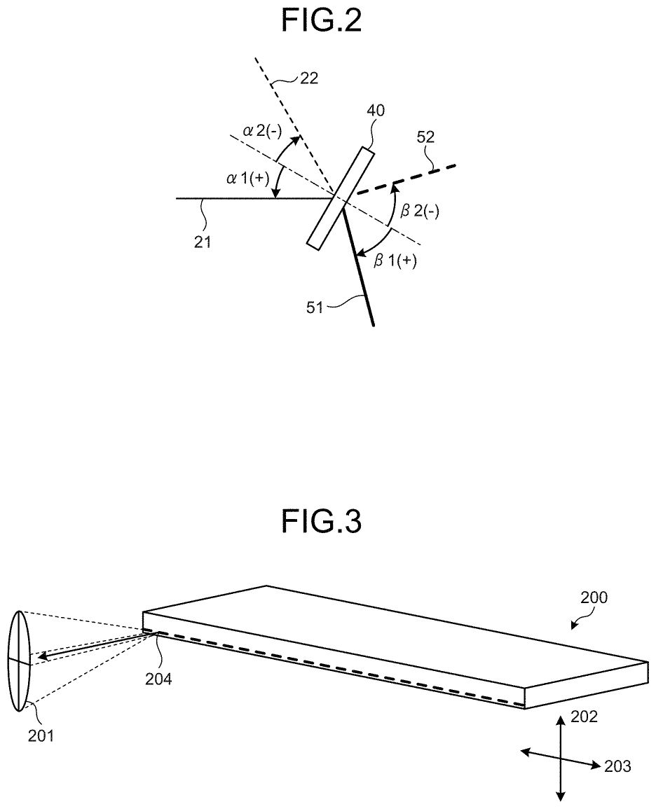

Next, details of the action of the transmission grating 40 will be described. FIG. 2 is a diagram for explaining the action of the transmission grating 40 constituting the laser system 101 according to the first embodiment. The reference character α1 indicates an incident angle of each beam constituting the first beam group 21 entering the transmission grating 40, and satisfies α1>0. The reference character α2 indicates an incident angle of each beam constituting the second beam group 22 entering the transmission grating 40, and satisfies α2<0. The reference character β1 indicates a diffraction angle of each beam constituting the first beam group 21, and satisfies β1>0. The reference character β2 indicates a diffraction angle of each beam constituting the second beam group 22, and satisfies β2<0.

The first beam group 21 and the second beam group 22 enter the transmission grating 40 in such a manner that α1 is positive and α2 is negative, that is, the positive and negative values of α1 and α2 are opposite to each other. The first beam 51 is plus primary diffracted light of the first beam group 21. The second beam 52 is minus primary diffracted light of the second beam group 22.

When the wavelength of a beam is λ, a grating spacing of the transmission grating 40 is d, and a diffraction order is m, a relation of the following formula (1) holds for α that is the incident angle in the transmission grating 40 and β that is the diffraction angle in the transmission grating 40.

sin α+sin β=mλ/d (1)

As is clear from the reference characters α1, α2, β1, and β2: the first beam 51, which is the plus primary diffracted light, is extracted by the incidence of the first beam group 21 on the transmission grating 40; and the second beam 52, which is the minus primary diffracted light, is extracted by the incidence of the second beam group 22 on the transmission grating 40. In addition, by arranging the optical elements in such a manner that α2=−α1 and β2=−β1, the first beam 51 and the second beam 52 oscillate at the same wavelength. By simultaneously using the plus primary diffracted light and the minus primary diffracted light of the transmission grating 40, the laser system 101 can simultaneously oscillate beams having the same wavelength by the first external resonator 1 and the second external resonator 2.

In the case of a general external resonator using the wavelength selectivity of a grating, it is difficult to simultaneously oscillate a plurality of light beams having the same wavelength. Therefore, an external resonator needs to use a wider wavelength band to increase the beam output. In order to widen the wavelength band, it is necessary to increase the number of types of laser elements, which complicates the configuration of the external resonator. In contrast, the laser system 101 according to the first embodiment can simultaneously oscillate a plurality of light beams having the same wavelength with a simple configuration.

In the laser system 101, a part of the first beam group 21 emitted from the first laser element 11 is reflected by the transmission grating 40 and enters the second laser element 12 in some cases. In addition, in the laser system 101, a part of the second beam group 22 emitted from the second laser element 12 is reflected by the transmission grating 40 and enters the first laser element 11 in some cases. In such a situation, the interaction between different laser elements occasionally causes a phenomenon called parasitic oscillation. If parasitic oscillation occurs, the laser oscillation becomes unstable and a problem such as; time variation of the beam output or time variation of the beam profile, of the laser system 101, can occurs.

In the first embodiment, when the reflectance of the partially reflective mirror 60 for the first beam 51 and the second beam 52 is R1, and the reflectance of the transmission grating 40 for the first beam 51 and the second beam 52 is R2, R1 is five or more times R2. If R1 is smaller than five times R1, the above parasitic oscillation is likely to occur. The laser system 101 can reduce the time variation of the beam output and the time variation of the beam profile since R1 is five or more times R2. In consideration of time degradation of a laser element or an optical element, R1 is desirably 10 or more times R2.

Next, a configuration example of the laser element in the first embodiment will be described. As the first laser element 11 and the second laser element 12, semiconductor laser bars can be used. FIG. 3 is a diagram illustrating a semiconductor laser bar 200 that is an example of a laser element to be provided in the laser system 101 according to the first embodiment. The semiconductor laser bar 200 illustrated in FIG. 3 is an end-face light emitting semiconductor laser. The semiconductor laser bar 200 includes a Fabry-Perot resonator. The Fabry-Perot resonator is not illustrated.

The semiconductor laser bar 200 emits a beam 201 having different diameters in the vertical and horizontal directions. The divergence angle of the beam 201 in the direction of a fast axis 202 is larger than the divergence angle of the beam 201 in the direction of a slow axis 203 perpendicular to the fast axis 202. In FIG. 1, the fast axis 202 coincides with the z axis. The slow axis 203 is in the xy plane.

The semiconductor laser bar 200 includes a plurality of light emitting points 204 arranged in a one-dimensional array. The light emitting points 204 are arranged in the direction of the slow axis 203. Each light emitting point 204 consists of a gain element that is a laser medium. A beam group emitted from the semiconductor laser bar 200 consists of the same number of beams 201 as the number of light emitting points 204 of the semiconductor laser bar 200. FIG. 1 illustrates one beam of the first beam group 21 emitted from the first laser element 11 and one beam of the second beam group 22 emitted from the second laser element 12. The beam group emitted from the semiconductor laser bar 200 consists of, for example, about 10 to 50 beams.

In order to apply the semiconductor laser bar 200 to an external resonator, one end face of the semiconductor laser bar 200 is coated with a high reflectance coating having a reflectance of, for example, 90% or more, and an opposite end face of the semiconductor laser bar 200 is coated with a low reflectance coating having a reflectance of, for example, 3% or less. Accordingly, an external resonator is formed between the end face of the semiconductor laser bar 200 coated with a high reflectance coating and the partially reflective mirror 60 installed outside the semiconductor laser bar 200.

The wavelength of the beam 201 emitted from the semiconductor laser bar 200 is a wavelength that is easily fiber coupled, for example, from 400 nm to 1100 nm. In the wavelength range of 900 nm to 1000 nm, semiconductor laser elements having higher output and longer life than those in other wavelength ranges are commercially available. Such a semiconductor laser element is suitable for high-power applications such as laser machining.

Note that the semiconductor laser bar 200 is an example of a laser element that is a light emitting source of the laser system 101. The laser element is not limited to the semiconductor laser bar 200. The laser element may be, for example, a surface light emitting semiconductor laser element. In addition, the wavelength of the laser element is not limited to 400 nm to 1100 nm, and is arbitrary.

In each of the first laser element 11 and the second laser element 12 illustrated in FIG. 1, beams having different wavelengths are emitted from the respective Light emitting points of a plurality of light emitting points. The first divergence-angle correction element 31 and the second divergence-angle correction element 32 reduce the divergence angle of the beams. The transmission grating 40 diffracts each beam constituting a beam group at an angle corresponding to the wavelength to converge the beams to a single beam. The laser system 101 converges, the first beam group 21 consisting of a plurality of beams dispersed from each other, to the single first beam 51. In addition, the laser system 101 converges, the second beam group 22 consisting of a plurality of beams dispersed from each other, to the single second beam 52. Accordingly, the laser system 101 can enhance the light condensing performance of the beams.

The light condensing performance referred to herein is a characteristic represented by the beam parameter product (BPP). The BOP is an index defined by the product of the radius at the beam waist at condensing light and a beam divergence half-angle after condensing light. The unit of BPP is expressed in mm·mrad. The smaller the value of BPS, the higher the light condensing performance, which means that the beam can be condensed in a finer region. As the beam can be condensed in a finer region, a higher energy density can be obtained. In the application of laser machining, as the energy density is higher, it is possible to improve the machining quality and the machining speed.

Many of general transmission gratings have high diffraction efficiency for one of s-polarized light and p-polarized light and low diffraction efficiency for the other. If the transmission grating 40 in the first embodiment is such a transmission grating, the transmission grating 40 diffracts, for example, 90% or more of the incident s-polarized light and transmits 50% or more of the incident p-polarized light. In this case, it is desirable for the first beam group 21 and the second beam group 22 entering the transmission grating 40 consist of only s-polarized light.

However, the laser light actually emitted from the laser element possibly contain a mixture of s-polarized light and p-polarized light. Even the laser light consisting mainly of s-polarized light can contain a few percent of p-polarized light. When the first beam group 21 and the second beam group 22 consisting mainly of s-polarized light entering the transmission grating 40, p-polarized light contained in the first beam group 21 and the second beam group 22 may pass through the transmission grating 40 in some cases. In this case, the p-polarized light having passed through the transmission grating 40 becomes stray light deviated from the normal optical path in the first external resonator 1 or the second external resonator 2. Generation of stray light possibly causes heating of components in the laser system 101 or deterioration in the light condensing performance of the output beam. Therefore, it is desirable that the laser system 101 can reduce the generation of stray light.

In order to reduce the generation of stray light, the laser system 101 may include polarization separation elements. The polarization separation elements are installed between the first laser element 11 and the transmission grating 40 and between the second laser element 12 and the transmission grating 40. Since the polarization degree of the first beam group 21 and the second beam group 22 entering the transmission grating 40 are increased by the polarization separation elements, the laser system 101 can reduce the generation of stray light.

In the laser system 101, a part of the first beam 51 or a part of the second beam 52 may become stray light in some cases. When stray light that is a part of the first beam 51 enters the optical path of the second beam 52 or when stray light that is a part of the second beam 52 enters the optical path of the first beam 51, parasitic oscillation possibly occurs. The laser system 101 may include a shield to reduce the generation of the stray light.

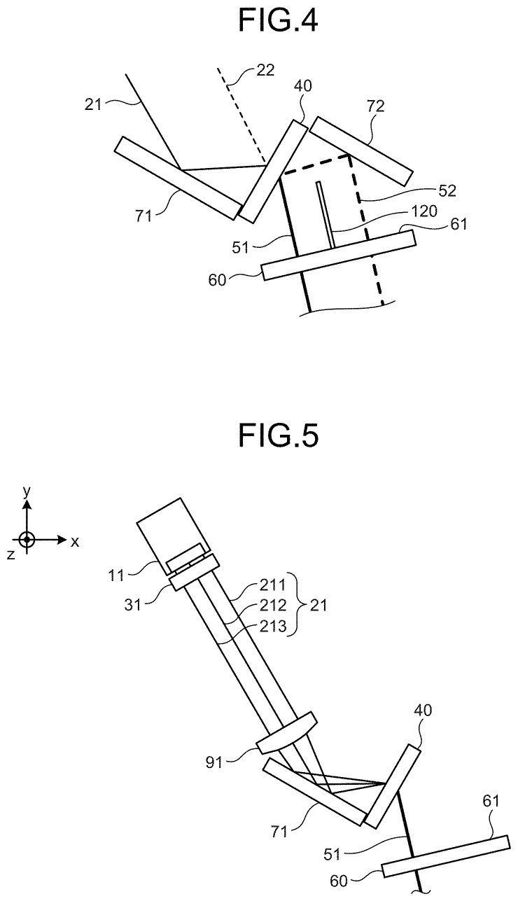

FIG. 4 is a diagram illustrating an installation example of a shield 120 in the laser system 101 according to the first embodiment. The shield 120 is a plate material that absorbs incident light. The shield 120 is provided between the optical path of the first beam 51 and the optical path of the second beam 52 between the transmission grating 40 and the part ally reflective mirror 60. The shield 120 shields the second beam 52 propagating toward the optical path of the first beam 51 and shields the first beam 51 propagating toward the optical path of the second beam 52. By providing the shield 120, the laser system 101 can reduce the generation of stray light. The position and range where the shield 120 is provided are not limited to the case illustrated in FIG. 4. The shield 120 is provided at least a part between the transmission grating 40 and the partially reflective mirror 60. Also in laser systems described in a second and subsequent embodiments, the shield 120 may be provided in the same manner as in the first embodiment.

Next, a positional relation of beams in an external resonator of the laser system 101 will be described. Here, the case of the first external resonator 1 is described as an example.

FIG. 5 is a diagram for explaining a positional relation of beams in an external resonator of the laser system 101 according to the first embodiment. FIG. 5 illustrates principal rays 211, 212, and 213 of three beams constituting the first beam group 21. In order to increase the energy density of the first beam 51 to be emitted from the partially reflective mirror 60, it is desirable that the principal rays 211, 212, and 213 intersect at one point on the transmission grating 40 and that the principal rays 211, 212, and 213 converge into the single first beam 51.

The first lens 91 is an example of a means for converging the principal rays 211, 212, and 213 at one point on the transmission grating 40. The transmission grating 40 is installed at a focal point of the first lens 91. The principal rays 211, 212, and 213 parallel to the optical axis of the first lens 91 intersect at one point on the transmission grating 40 or are sufficiently close to each other on the transmission grating 40. Being sufficiently close refers to being close enough that the beams can be diffracted and converged to the single first beam 51.

By diffracting each beam at an angle corresponding to the wavelength of the beam, the principal rays 211, 212, and 213 converge to the single first beam 51. Accordingly, the first beam 51 emitted from the partially reflective mirror 60 has higher light condensing performance than the first beam group 21 emitted from the first laser element 11. Note that the positional relation of the beams of the second beam group 22 in the second external resonator 2 is similar to that in the case of the beams of the first beam group 21 in the first external resonator 1. In the above description, the number of beams constituting a beam group is three, but the same applies to a case where the number of beams constituting a beam group is more than three.

In the first embodiment, the configuration including the first reflective mirror 71 and the second reflective mirror 72 has been described, but the laser system 101 may omit the first reflective mirror 71 depending on the arrangement of laser elements. That is, the laser system 101 may include only the second reflective mirror 72 instead of the first reflective mirror 71 and the second reflective mirror 72. Even in the case of including only the second reflective mirror 72, the laser system 101 can obtain a similar effect to the case of including the first reflective mirror 71 and the second reflective mirror 72.

In the first embodiment, there is a difference between the optical path length of the first external resonator 1 and the optical path length of the second external resonator 2 due to constraints on the physical arrangement of the laser elements or the optical elements and the like an some cases. In this case, the laser system 101 can reduce the influence of the optical path length difference to a negligible extent by collimating each beam entering the transmission grating 40.

According to the first embodiment, in the laser system 101, the partially reflective mirror 60 is shared by the first external resonator 1 and the second external resonator 2. The laser system 101 can reduce the number of components by making the first external resonator 1 and the second external resonator 2 share the partially reflective mirror 60, which is an optical element constituting the resonator. The laser system 101 can achieve high output by coupling the beams oscillated by the first external resonator 1 and the second external resonator 2 and outputting the coupled beam. In addition, the laser system 101 can achieve high output without increasing the light density in optical elements other than the transmission grating 40. The laser system 101 can reduce damage to each optical element due to high light intensity received by each optical element.

Furthermore, the laser system 101 can simultaneously oscillate a plurality of beams having the same wavelength by appropriately selecting the incident angle and the emission angle of the transmission grating 40. The laser system 101 can increase the output without widening the wavelength band. In the laser system 101, a plurality of optical elements to be installed as needed can be shared by the first external resonator 1 and the second external resonator 2. By making the first external resonator 1 and the second external resonator 2 share the optical elements, the laser system 101 can make it hard for differences in beam characteristics to occur due to the state of adjustment of the optical elements or the aging of the optical elements. The laser system 101 can reduce variations in beam characteristics of the beams oscillated by the first external resonator 1 and by the second external resonator 2.

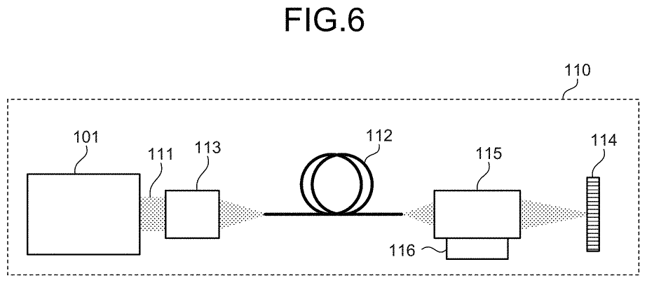

Next, a configuration example of a laser machine to which the laser system 101 according to the first embodiment is applied will be described. FIG. 6 is a diagram illustrating a configuration example of a laser machine 110 to which the laser system 101 according to the first embodiment is applied. The laser machine 110 irradiates a workpiece 114 with laser light 111 to machine the workpiece 114. The machining by the laser machine 110 is laser machining such as cutting or welding of the workpiece 114.

The laser machine 110 includes: the laser system 101 that emits laser light 111; an optical fiber 112 through which the laser light 111 propagates; a condensing optical system 113; a machining optical system 115; and a drive mechanism 116. The condensing optical system 113 condenses the laser light 111 on the incident end face of the optical fiber 112. The machining optical system 115 condenses the laser light 111 emitted from the optical fiber 112 on the workpiece 114. The drive mechanism 116 relatively moves the workpiece 114 and the machining optical system 115 in the three-dimensional direction.

The workpiece 114 is, for example, a metal plate made of iron, stainless steel, or the like. The laser machine 110 can perform laser machining of a metal plate by including the laser system 101 suitable for high-power applications. The configuration of the laser machine 110 described here is an example and may be appropriately changed. The laser system 101 can also be applied to a 3D printer or the like by being combined with a configuration of a generally known laser machine. Similarly to the laser system 101, laser systems described in the second and subsequent embodiments can also be applied to the laser machine 110 that cuts or welds the workpiece 114, or another laser machine.

### Second Embodiment

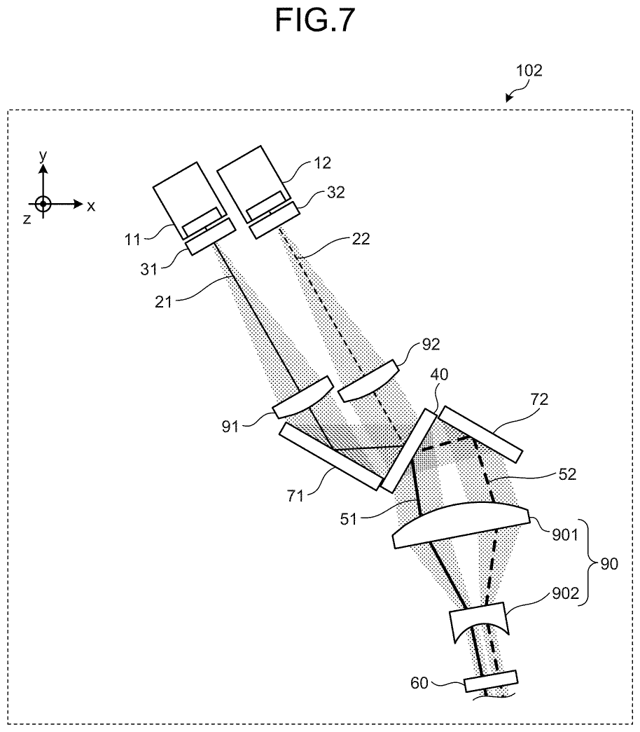

FIG. 7 is a schematic diagram illustrating a configuration of a laser system 102 according to a second embodiment. In the second embodiment, the same components as those in the first embodiment are denoted by the same reference signs, and the configuration different from that in the first embodiment will be mainly described.

The laser system 102 includes a reduction optical system 90 in addition to the configuration of the laser system 101 according to the first embodiment. The reduction optical system 90 is arranged between the transmission grating 40 and the partially reflective mirror 60.

The reduction optical system 90: reduces the diameter of the first beam 51 traveling from the transmission grating 40 to the partially reflective mirror 60 and the diameter of the second beam 52 traveling from the transmission grating 40 to the partially reflective mirror 60; and reduces the distance between the principal ray of the first beam 51 traveling from the transmission grating 40 to the partially reflective mirror 60 and the principal ray of the second beam 52 traveling from the transmission grating 40 to the partially reflective mirror 60. The reduction optical system 90 consists of a transfer optical system having optical power in the xy direction. The reduction optical system 90 according to the second embodiment is constituted by a first lens 901 and a second lens 902.

The laser system 102 reduces the beam size of each of the first beam 51 and the second beam 52 and shortens the distance between the first beam 51 and the second beam 52 with the reduction optical system 90. Therefore, the size of the partially reflective mirror 60 and the size of an optical element to be installed as needed can be reduced compared with the case where the reduction optical system 90 is not provided. The laser system 102 can obtain more beam output without increasing the size of the partially reflective mirror 60 and the size of the optical element.

If there is a difference between the optical path length of the first external resonator 1 and the optical path length of the second external resonator 2: due to the deflection of the first beam group 21 by the first reflective mirror 71; and due to the deflection of the second beam 52 by the second reflective mirror 72; the laser system 102 may eliminate the optical path length difference by bending the optical paths or the like. In this case, the laser system 102 may cause the first beam 51 and the second beam 52 to intersect each other and then cause the first beam 51 and the second beam 52 to be parallel to each other. Specifically, a mirror that deflects the first beam 51 by 90 degrees in the xy plane is provided on the optical path of the first beam 51 between the transmission grating 40 and the first lens 91 to cause the first beam 51 and the second beam 52 to intersect each other. Furthermore, a mirror that deflects the first beam. 51 having intersected the second beam 52 by 90 degrees in the xy plane is provided to cause the first beam 51 and the second beam 52 to be parallel to each other. Accordingly, the optical path length difference is eliminated by the distance between the two mirrors.

According to the second embodiment, the laser system 102 can downsize the optical system after converging a plurality of beams by the transmission grating 40. Accordingly, the laser system 102 can obtain high output while downsizing the optical system.

### Third Embodiment

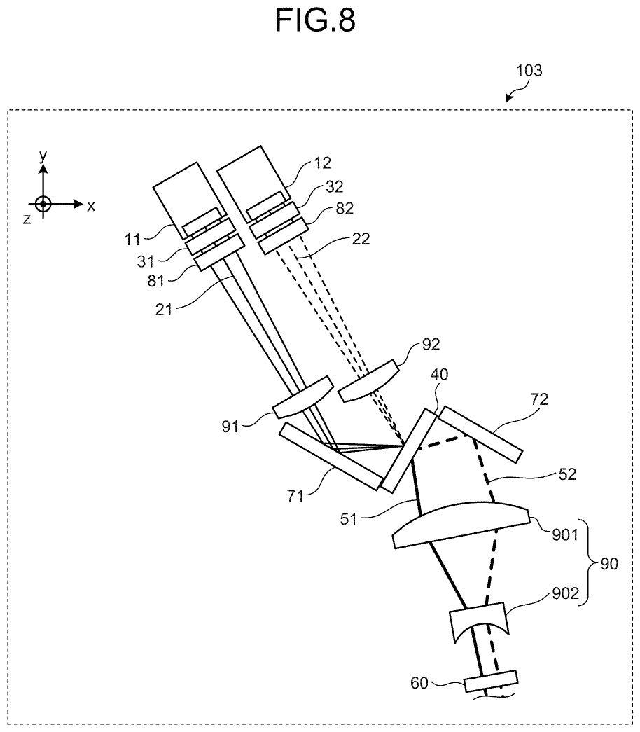

FIG. 8 is a schematic diagram illustrating a configuration of a laser system 103 according to a third embodiment. In the third embodiment, the same components as those in the first or second embodiment are denoted by the same reference signs, and the configuration different from that in the first or second embodiment will be mainly described.

The laser system 103 includes a first beam rotation element 81 and a second beam rotation element 82 that are beam rotation elements in addition to the configuration of the laser system 102 according to the second embodiment. The first beam rotation element 81 is arranged between the first divergence-angle correction element 31 and the first lens 91. The second beam rotation element 82 is arranged between the second divergence-angle correction element 32 and the second lens 92.

The first beam rotation element 61 rotates each beam of the First beam group 21 around the principal ray of the beam. The second beam rotation element 82 rotates each beam of the second beam group 22 around the principal ray of the beam. That is, the first beam rotation element 81 and the second beam rotation element 82, which are beam rotation elements, rotate each beam of the first beam group 21 and each beam of the second beam group 22 around the principal ray of the beam.

Note that FIG. 8 illustrates principal rays of three beams constituting the first beam group 21 and principal rays of three beams constituting the second beam group 22. The configuration in the third embodiment exhibits a remarkable effect when the laser elements are semiconductor laser bars. In the following description in the third embodiment, each of the first laser element 11 and the second laser element 12 is a semiconductor laser bar.

The first beam rotation element 81 is combined with the first divergence-angle correction element 31 to superimpose a plurality of beams constituting the first beam group 21 on the transmission grating 40. The second beam rotation element 82 is combined with the second divergence-angle correction element 32 to superimpose a plurality of beams constituting the second beam group 22 on the transmission grating 40.

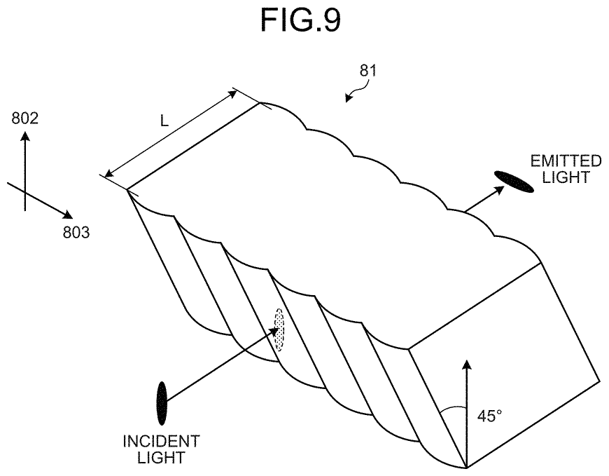

Next, a configuration example of a beam rotation element will be described. FIG. 9 is a diagram illustrating an example of a beam rotation element to be provided in the laser system 103 according to the third embodiment. FIG. 9 illustrates a configuration example of the first beam rotation element 81. The second beam rotation element 82 is similar to the following description for the first beam rotation element 81.

The beam rotation element is a rotation optical system that rotates an image by 90 degrees around the optical axis. The first beam rotation element 81 illustrated in FIG. 9 is a lens array. On each of the face of the first beam rotation element 81 closer to the first laser element 11 and the face opposite to the first laser element 11, a plurality of cylindrical faces arranged in one direction is formed. Each cylindrical face is a convex face. Each cylindrical face is inclined by 45 degrees with respect to a vertical axis 802 perpendicular to the horizontal plane. The array pitch of a plurality of lenses is the same as the array pitch of the light emitting points of the semiconductor laser bar. When the focal length due to refraction on the cylindrical face is f, the distance L between the cylindrical face closer to the first laser element 11 and the cylindrical face opposite to the first laser element 11 is 2f.

The major axis direction of the incident light that is a beam entering the first beam rotation element 81 from the first laser element 11 is the direction of the vertical axis 802. The minor axis direction of the incident light is the direction of a horizontal axis 803 contained in the horizontal plane. On the other hand, the major axis direction of the emitted light that is a beam emitted from the first beam rotation element 81 after the incidence on the first beam rotation element 81 from the first laser element 11 is the direction of the horizontal axis 803. The minor axis direction of the emitted light is the direction of the vertical axis 802. As described above, the light, whose major axis direction and minor axis direction are reversed from those of the incident light, is emitted from the first beam rotation element 81. In this manner, the first beam rotation element 81 rotates the beam by 90 degrees around the optical axis.

For example, in a semiconductor laser bar that emits a beam of 900 nm to 1000 nm, the total angle of the divergence angle of the beam in the slow axis direction is generally about 5 degrees to 10 degrees, whereas the total angle of the divergence angle of the beam in the fast axis direction is about 30 degrees to 60 degrees. That is, the divergence angle of a beam in the fast axis direction is larger than the divergence angle of the beam in the slow axis direction. In addition, the light condensing performance of the semiconductor laser bar in the slow axis direction is lower than the light condensing performance of the semiconductor laser bar in the fast axis direction.

A semiconductor laser bar has a deformation called a smile due to the manufacturing process of the semiconductor laser bar in some cases. Due to the smile, positional variation in the fast axis direction occurs at the light emitting points. According to the third embodiment, by rotating a beam by 90 degrees by the beam rotation element, the direction in which the positions of the light emitting points vary due to the smile is converted into the slow axis direction in which the light condensing performance is relatively low. Accordingly, the laser system 103 can reduce deterioration in the light condensing performance caused by the smile.

For example, in a case where the first divergence-angle correction element 31 consisting of a lens having a cylindrical face is used, by installing the first divergence-angle correction element 31 slightly inclined with respect to the xy plane, each beam of the first beam group 21 is emitted from the first divergence-angle correction element 31 in a state of being angled in the z direction. When the first beam rotation element 81 is installed immediately after the first divergence-angle correction element 31, each beam is converted from a state of being angled in the z direction to a state of being angled in the xy plane by passing through the first beam rotation element 81. By appropriately setting the inclination angle of the first divergence-angle correction element 31 with respect to the xy plane, the principal rays of the beams can be brought closer to each other while the beams travel toward the transmission grating 40.

In the first and second embodiments, each of the first lens 91 and the second lens 92 has played a role in superimposing a plurality of beams on the transmission grating 40. In the third embodiment, a combination of the divergence-angle correction element and the beam rotation element can play the above described role. Therefore, the positions of the first lens 91 and the second lens 92 or the focal lengths of the first lens 91 and the second lens 92 in the third embodiment may be different from those in the first or second embodiment.

According to the third embodiment, the laser system 103 can obtain high output while reducing the deterioration in the light condensing performance caused by the smile.

### Fourth Embodiment

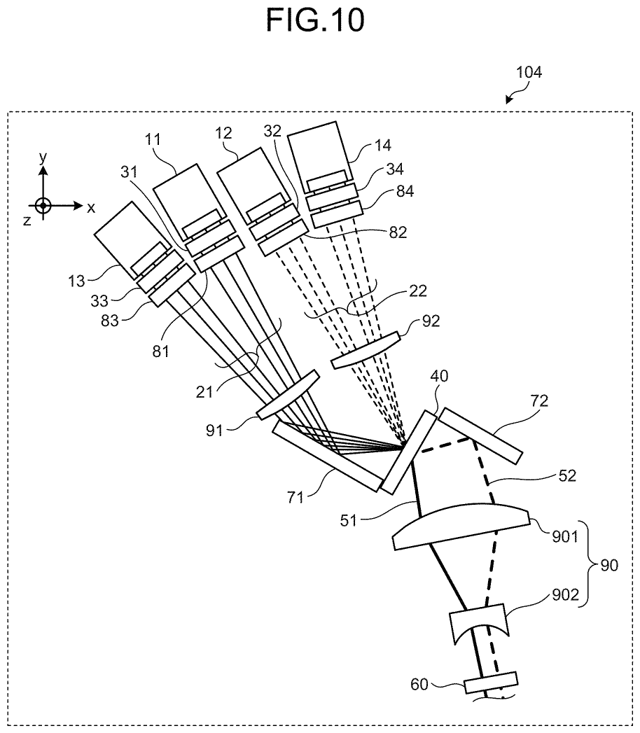

FIG. 10 is a schematic diagram illustrating a configuration of a laser system 104 according to a fourth embodiment. The laser system 104 includes a plurality of first laser elements and a plurality of second laser elements. In the fourth embodiment, the same components as those in the first to third embodiments are denoted by the same reference signs, and the configuration different from those in the first to third embodiments will be mainly described.

The laser system 104 includes a first laser element 13 and a second laser element 14 in addition to the configuration of the laser system 103 according to the third embodiment. That is, the laser system 104 includes two first laser elements 11 and 13 and two second laser elements 12 and 14. The first laser element 13 emits the first beam group 21 that is one or a plurality of beams. The second laser element 14 emits the second beam group 22 that is one or a plurality of beams.

The laser system 104 further includes a first divergence-angle correction element 33, a second divergence-angle correction element 34, a first beam rotation element 83, and a second beam rotation element 84. The first divergence-angle correction element 33 corrects the divergence angle of the first beam group 21 emitted from the first laser element 13. The second divergence-angle correction element 34 corrects the divergence angle of the second beam group 22 emitted from the second laser element 14. The first beam rotation element 83 is arranged between the first divergence-angle correction element 33 and the first lens 91. The first beam rotation element 83 rotates each beam of the first beam group 21 around the principal ray of the beam. The second beam rotation element 84 is arranged between the second divergence-angle correction element 34 and the second lens 92. The second beam rotation element 84 rotates each beam of the second beam group 22 around the principal ray of the beam. The transmission grating 40: converges the first beam group 21 emitted from each of the first laser elements 11 and 13 to the first beam 51; and converges the second beam group 22 emitted from each of the second laser elements 12 and 14 to the second beam 52.

The first laser element 11 and the first laser element 13 emit beams having different wavelengths from each other. The second laser element 12 and the second laser element 14 emit beams having different wavelengths from each other. The first beam group 21 and the second beam group 22 may include beams having the same wavelength. The number of first laser elements to be provided in the laser system 104 may be three or more. The number of second laser elements to be provided in the laser system 104 may be three or more. When a semiconductor laser bar having a beam output of 200 W is used, the laser system 104 may obtain a beam output of 2 kW or more by providing 10 or more semiconductor laser bars for the first laser elements and the second laser elements together. Accordingly, the laser system 104 can achieve high output suitable for laser machining.

According to the fourth embodiment, by including a plurality of first laser elements and a plurality of second laser elements, the laser system 104 can achieve high output while maintaining high light condensing performance by converging a plurality of beams in the external resonator.

### Fifth Embodiment

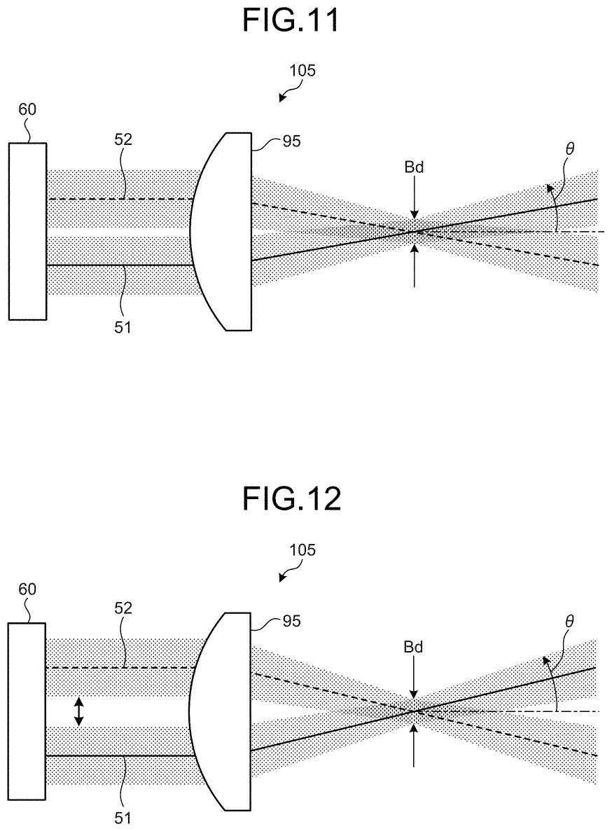

FIG. 11 is a first diagram illustrating a configuration of a laser system 105 according to a fifth embodiment. FIG. 12 is a second diagram illustrating a configuration of the laser system 105 according to the fifth embodiment. The laser system 105 according to the fifth embodiment can change the relative position of the first beam 51 and the second beam 52 in the xy plane. In the fifth embodiment, the same components as those in the first to fourth embodiments are denoted by the same reference signs, and the configuration different from those in the first to fourth embodiments will be mainly described. FIGS. 11 and 12 illustrate the first beam 51, the second beam 52, the partially reflective mirror 60, and a condenser lens 95 in the xy plane. The first beam 51 and the second beam 52 having passed through the partially reflective mirror 60 enter the condenser lens 95.

The laser system 105 can change the light condensing performance of a beam output from the laser system 105 by changing the relative position between the first beam 51 and the second beam 52. Here, it is assumed that the first beam 51 and the second beam 52 output from the laser system 105 are used as one beam. The fact that the distance between the first beam 51 and the second beam 52 changes means that the light condensing performance of a beam output from the laser system 105 charges.

As illustrated in FIGS. 11 and 12, the first beam 51 and the second beam 52 having passed through the partially reflective mirror 60 propagate in parallel to each other. Here, it is assumed that the first beam 51 and the second beam 52 are sufficiently collimated. FIG. 11 illustrates that the distance between the first beam 51 and the second beam 52 is narrowed. FIG. 12 illustrates that the distance between the first beam 51 and the second beam 52 is widened.

In the cases illustrated in FIGS. 11 and 12, the first beam 51 and the second beam 52 emitted from the partially reflective mirror 60 are condensed by the condenser lens 95. That is, the first beam 51 and the second beam 52 are focused on the focal point with the same focal length in the state illustrated in FIG. 11 and the state illustrated in FIG. 12. The first beam 51 and the second beam 52 are condensed at the focal point and then diffused.

In the state illustrated in FIG. 11 and the state illustrated in FIG. 12, a beam waist diameter Bd of the beam consisting of the first beam 51 and the second beam 52 is the same. A spread angle θ of the beam consisting of the first beam 51 and the second beam 52 is larger in the case illustrated in FIG. 12 than in the case illustrated in FIG. 11. In this manner, the laser system 105 changes the light condensing performance of the beam output from the laser system 105 by changing the distance between the first beam 51 and the second beam 52. That is, the laser system 105 can change the BPP.

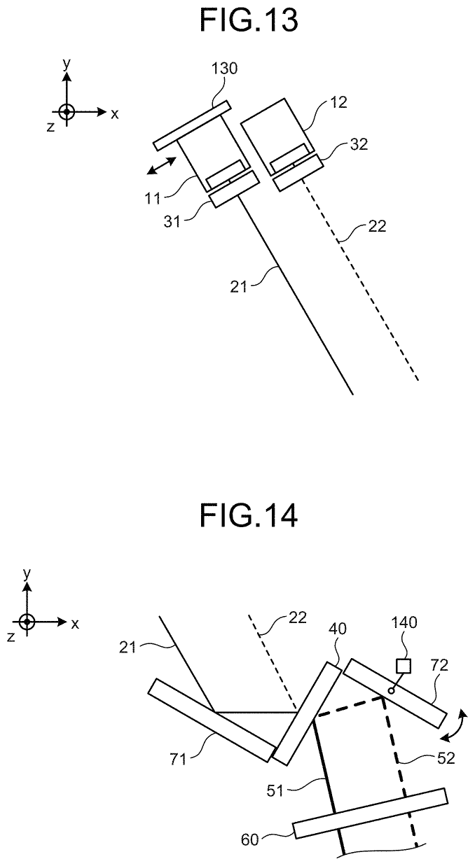

Next, a specific example of a position changer for changing the relative position between the first beam 51 and the second beam 52 will be described. FIG. 13 is a diagram illustrating a first example of a position changer of the laser system 105 according to the fifth embodiment. In FIG. 13, the position changer is a mechanism 130 that moves the first laser element 11 in the xy plane. The laser system 105 changes the distance between the first beam 51 and the second beam 52 by moving the first laser element 11 relative to the second laser element 12.

The mechanism 130 moves the first laser element 11 in a direction in which the distance between the first beam group 21 and the second beam group 22 is narrowed and in a direction in which the distance between the first beam group 21 and the second beam group 22 is widened. Note that the position changer is not limited to the mechanism 130 that moves the first laser element 11, and may be a mechanism that moves the second laser element 12.

FIG. 14 is a diagram illustrating a second example of the position changer of the laser system 105 according to the fifth embodiment. In FIG. 14, the position changer is a mechanism 140 that rotates the second reflective mirror 72 that is a beam deflection element. The mechanism 140 changes the traveling direction of the second beam 52 by rotating the second reflective mirror 72 around the z axis to change the distance between the first beam 51 and the second beam 52.

The position changer is not limited to the one illustrated in FIG. 13 or 14. For example, the position changer may include a glass substrate installed on the optical path of the first beam group 21 and a mechanism that rotates the glass substrate around the z axis, and move the first beam group 21 in the xy plane by the rotation of the glass substrate. The position changer may translate or deflect the first beam 51 or the second beam 52 in the xy plane using a bending optical path constituted by a plurality of mirrors. The position changer may change the relative position of the first beam 51 and the second beam 52 by a combination of various methods.

According to the fifth embodiment, the laser system 105 can set optimum light condensing performance according to an object to be machined.

The configuration described in each of the above embodiments is an example of the contents of the present disclosure. The configuration of each of the embodiments can be combined with another known technique. The configurations of the respective embodiments may be appropriately combined. A part of the configuration of each of the embodiments can be omitted or changed without departing from the gist of the present disclosure.

### REFERENCE SIGNS LIST

1 first external resonator; 2 second external resonator; 11, 13 first laser element; 12, 14 second laser element; 21 first beam group; 22 second beam group; 31, 33 first divergence-angle correction element; 32, 34 second divergence-angle correction element; 40 transmission grating; 51 first beam; 52 second beam; 60 partially reflective mirror; 61 incidence plane; 71 first reflective mirror; 72 second reflective mirror; 81, 83 first beam rotation element; 82, 84 second beam rotation element; 90 reduction optical system; 91, 901 first lens; 92, 902 second lens; 95 condenser lens; 101, 102, 103, 104, 105 laser system; 110 laser machine; 111 laser light; 112 optical fiber; 113 condensing optical system; 114 workpiece; 115 machining optical system; 116 drive mechanism; 120 shield; 130, 140 mechanism; 200 semiconductor laser bar; 201 beam; 202 fast axis; 203 slow axis; 204 light emitting point; 211, 212, 213 principal ray; 802 vertical axis; 803 horizontal axis.

1. A laser system comprising:
a first laser element adapted to emit a first beam group, the first beam group being one or a plurality of beams, and adapted to constitute one end of a first external resonator to cause the first beam group to resonate;
a second laser element adapted to emit a second beam group, the second beam group being one or a plurality of beams, and adapted to constitute one end of a second external resonator to cause the second beam group to resonate;
a diffractive optical element:
to which the first beam group and the second beam group enter in such a manner that positive and negative angles of incidence of each beam of the first beam group and each beam of the second beam group are opposite to each other; and
from which a first beam being the converged first beam group, and a second beam being the converged second beam group, are emitted;
a partially reflective element adapted to constitute an opposite end of the first external resonator and an opposite end of the second external resonator, adapted to reflect a part of the first beam and a part of the second beam, and adapted to transmit the remainder of the first beam and the remainder of the second beam; and
a beam deflection element adapted to deflect the second beam emitted from the diffractive optical element toward the partially reflective element.

2. The laser system according to claim 1, wherein
the first beam is a plus primary diffracted light of the first beam group, and
the second beam is a minus primary diffracted light of the second beam group.

3. The laser system according to claim 1, wherein
an incident plane of the partially reflective element to which the first beam and the second beam enter is a single plane.

4. The laser system according to claim 1, wherein
a reflectance of the partially reflective element for the first beam and the second beam is five or more times a reflectance of the diffractive optical element for the first beam group and the second beam group.

5. The laser system according to claim 1, further comprising a reduction optical system adapted:
to reduce a diameter of the first beam traveling from the diffractive optical element to the partially reflective element and a diameter of the second beam traveling from the diffractive optical element to the partially reflective element; and
to reduce a distance between a principal ray of the first beam traveling from the diffractive optical element to the partially reflective element and a principal ray of the second beam traveling from the diffractive optical element to the partially reflective element.

6. The laser system according to claim 1, further comprising a beam rotation element adapted to rotate each beam of the first beam group and each beam of the second beam group around a principal ray of the beam.

7. The laser system according to claim 1 comprising:
a plurality of the first laser elements; and
a plurality of the second laser elements, wherein
the diffractive optical element:
is adapted to converge the first beam group, emitted from each of the first laser elements, to the first beam; and
is adapted to converge the second beam group, emitted from each of the second laser elements, to the second beam.

8. The laser system according to claim 1, further comprising a position changer adapted to change a relative position of the first beam and the second beam in a plane including the principal ray of the first beam and the principal ray of the second beam.

9. The laser system according to claim 8, wherein the position changer is a mechanism adapted to move the first laser element relative to the second laser element.

10. The laser system according to claim 8, wherein the position changer is a mechanism adapted to rotate the beam deflection element.

11. The laser system according to claim 1, further comprising a shield provided between an optical path of the first beam and an optical path of the second beam.
